(19) United States
(12) Patent Application Publication
(10) Pub. No.: US 2008/0017936 A1
(43) Pub. Date: Jan. 24, 2008

(54) Semiconductor device structures (gate stacks) with charge compositions

(75) Inventors: Douglas A. Buchanan, Winnipeg (CA); Eduard A. Cartier, New York, NY (US); Kevin K. Chan, Staten Island, NY (US); Leland Chang, New York, NY (US); Christopher P. D'Emic, Ossining, NY (US); Martin M. Frank, Bronx, NY (US); Evgeni Gusev, Saratoga, CA (US); Jin-Ping Han, Fishkill, NY (US); Rajarao Jammy, Hopewell Junction, NY (US); Vamsi K. Paruchuri, New York, NY (US); Sufi Zafar, Briarcliff Manor, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: International Business Machines Corporation, Armonk, NY (US)

(21) Appl. No.: 11/477,707

(22) Filed: Jun. 29, 2006

(51) Int. Cl. H01L 29/94; H01L 29/76; H01L 31/00

(52) U.S. Cl. 257/411

(57) ABSTRACT

A semiconductor structure, particularly a gate stack, useful in field effect transistors (FETs) in which the threshold voltage thereof is controlled by introducing a fixed spatial distribution of electric charge density to the gate dielectric material and a method of forming the same are provided. nFETs and/or pFETs structures are disclosed. In accordance with the present invention, the fixed spatial distribution of electric charge density of the gate stack or FET denotes an electrical charge density that occupies space which remains substantially constant as a function of time under device operation conditions and is non-zero at least at one location within the dielectric material or at its interface with the channel, gate electrode, spacer, or any other structural elements of the device.

### FIELD OF THE INVENTION

The present invention relates to a semiconductor structure, and more particularly to a gate stack useful in field effect transistors (FETs) in which the threshold voltage and flatband voltage thereof is controlled by introducing a fixed spatial distribution of electric charge density to the gate dielectric material. nFETs and/or pFETs structures are disclosed. The present invention also provides a method of fabricating such a semiconductor structure, particularly a gate stack where the gate dielectric has a fixed spatial distribution of electric charge density, which is capable of controlling the threshold voltage/flatband voltage of the device.

### BACKGROUND OF THE INVENTION

In current semiconductor technologies, the threshold voltages of metal oxide semiconductor field effect transistors (MOSFETs) are set by choosing an appropriate channel doping concentration for a give gate dielectric thickness and gate material (usually n+ or p+ polysilicon).

In such technologies, it is well known that replacement of SiO₂ (the current gate dielectric of choice) and/or of polysilicon (the current gate conductor of choice) has been a very urgent task for complementary metal oxide semiconductor (CMOS) device scaling. A lot of effort has been made on seeking and selecting proper metal gates for high dielectric constant k (k of greater than that of silicon dioxide) CMOS devices. For example, dual metal gates including compound metals or a doped fully silicide metal gate have been investigated in order to obtain the ideal pFET and/or nFET workfunctions. So far, a lot of progress has been made, but no obvious successful approach has been report for both pFETs and nFETs.

In high threshold voltage (low leakage) devices, scaling of the effective gate dielectric thickness means that the channel doping must be very high (on the order of about 6×10¹⁷ atoms/cm³ or greater). This results in increased random threshold voltage variation due to dopant fluctuation, a mobility degradation due to increased electrical field, and an increased band-to-band tunneling leakage. In particular, dopant fluctuation is expected to be a major yield limitation in future technologies. Adjustment of the device threshold voltage by other means such as, for example, the gate workfunction, can alleviate these issues because a lower channel doping may be used. With a low channel doping, short-channel effects would likely be controlled by the use of a thin-body semiconductor-on-insulator (SOI) device structure (e.g., fully depleted SOI, ultra-thin SOI, or a double gate FET) instead of halo implants as used in current SOI or bulk designs.

A viable CMOS technology requires at least two different threshold voltages for each pFET and nFET device to allow for high performance and low leakage options. This becomes challenging for gate workfunction engineering in particular since undoped body devices require that at least four different gate materials be integrated onto the same semiconductor wafer. This problem can be solved by previously proposed methods such as ion implantation to selectively change the gate electrode materials, but these prior art strategies are often limited in the range of gate workfunctions that can be achieved and they can only be applied to a limited set of material combinations.

In view of the above, there is a continued need for providing a semiconductor structure having threshold voltage/flatband voltage control as well as a method of fabricating such a semiconductor structure.

### SUMMARY OF THE INVENTION

The present invention provides a semiconductor structure, particularly a gate stack, useful in field effect transistors (FETs) in which the threshold voltage/flatband voltage thereof is controlled by introducing a fixed spatial distribution of electric charge density to the gate dielectric material. nFETs and/or pFETs structures are disclosed. For nFETs, a threshold voltage/flatband voltage of from about 200 to about 50 mV from the conduction band edge can be achieved, while for pFETs a threshold voltage/flatband voltage of from about 200 mV to about 50 mV from the valence band edge can be can be achieved.

The term “fixed spatial distribution of electric charge density” is used throughout this application to denote an electrical charge density that occupies space which remains substantially constant as a function of time under device operation conditions and is non-zero at least at one location within the dielectric material or at its interface with the channel, gate electrode, spacer, or any other structural elements of the device. In accordance with the present invention, a fixed spatial distribution of electric charge density of from about 1×10¹² to about 1×10¹³ cm⁻² is provided to each nFET or PFET. When both nFETs and pFETs are present, a fixed spatial distribution of electric charge density of from about 1×10¹² to about 1×10¹³ cm⁻² is provided for the nFET, while a fixed spatial distribution of electric charge density of from about 1×10¹³ to about 5×10³ cm⁻² is provided for the pFET.

Structure/chemical features that can cause the fixed spatial distribution of electric charge density in the gate dielectric include vacancies, suboxides, interstitials, dangling bonds, grain boundaries, phase boundaries, stacking faults, bond angle density porosity variation, strained bonds, foreign atoms or functional groups or interfaces between the dielectrics of different composition. The techniques used in forming these structure/chemical features will be described in greater detail herein below.

In general terms, the present invention provides a semiconductor structure comprising:

at least one gate stack disposed on a semiconductor substrate, said at least one gate stack including, from bottom to top, a gate dielectric and a gate electrode, wherein said gate dielectric contains a fixed spatial distribution of electric charge density that stabilizes the gate stack's threshold voltage and flatband voltage to a targeted value.

The at least one gate stack may be a pFET or an nFET.

A semiconductor structure including both an nFET and a pFET on the same semiconductor substrate is also provided. Such a structure comprises:

at least one nFET and at least one pFET located on a semiconductor substrate, each FET including a gate stack including, from bottom to top, a gate dielectric and a gate electrode, wherein said gate dielectric of said at least one nFET contains a first fixed spatial distribution of electric charge density and said gate dielectric of said at least one pFET includes a second fixed spatial distribution of electric charge density that is different from said first, wherein each of the first and second fixed spatial electric charge densities stabilizes its FET's threshold voltage and flatband voltage to a targeted value.

In addition to the semiconductor structure mentioned above, the present invention also provides a method of fabricating the same. In general terms, the method of the present invention comprises:
providing a gate stack on a semiconductor substrate, said gate stack including, from bottom to top, a gate dielectric and gate electrode; and
applying a bias to said gate stack, wherein said gate dielectric contains a fixed spatial distribution of electric charge density that stabilizes the gate stack's threshold voltage and flatband voltage to a targeted value.

### BRIEF DESCRIPTION OF THE DRAWINGS

FIGS. 1A-1F are pictorial representations (through cross sectional views) depicting the basic processing steps employed in the present invention for fabricating a gate stack in which a fixed spatial distribution of electric charge density within the gate dielectric is used in controlling the threshold voltage and flatband voltages thereof.

FIG. 2 is a pictorial representation (through a cross sectional view) depicting a semiconductor structure of the present invention including at least one nFET and at least one pFET wherein the FETs include substantially the same structural elements with different spatial distribution of electrical charge density on each of the FETs of different conductivity.

### DETAILED DESCRIPTION OF THE INVENTION

The present invention, which provides a semiconductor structure in which a fixed spatial distribution of electric charge density is provided to a gate dielectric material for use in controlling the threshold/flatband voltages thereof as well as a method of fabricating such a structure, will now be described in greater detail by referring to the following discussion and drawings that accompany the present application. It is observed that the drawings are provided for illustrative proposes and, as such, they are not drawn to scale.

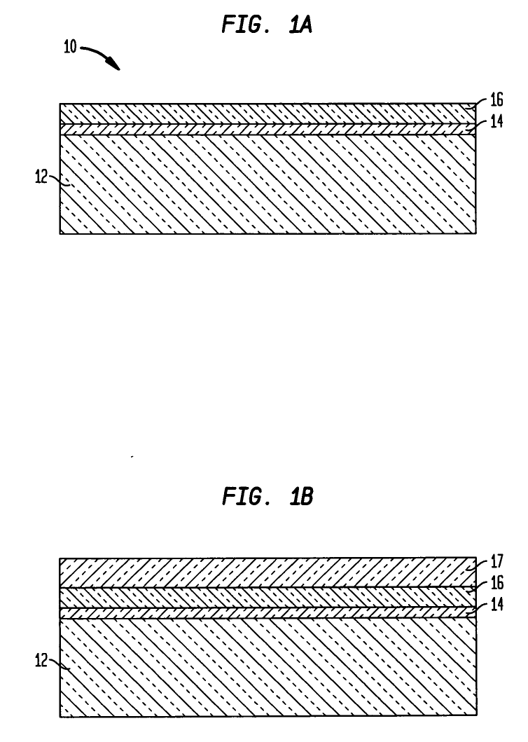

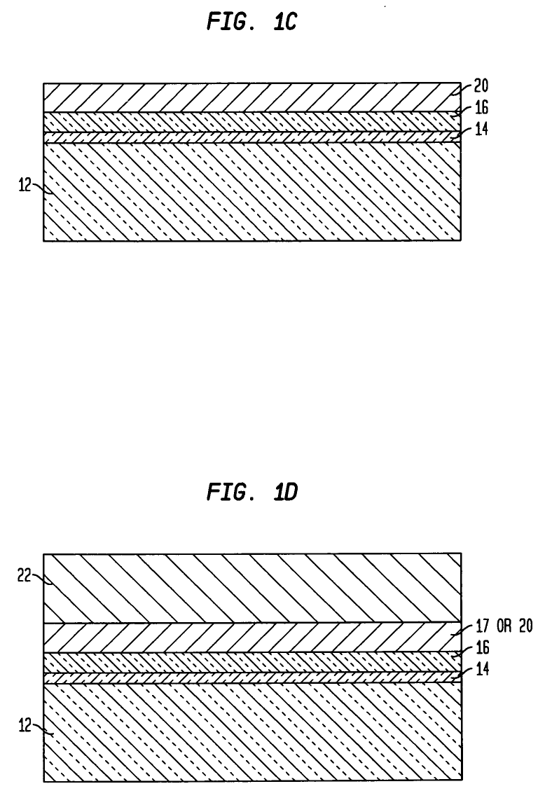

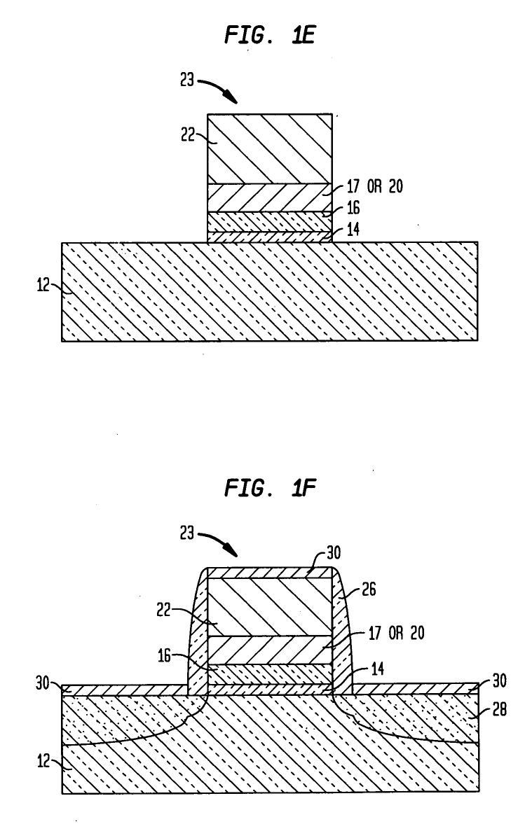

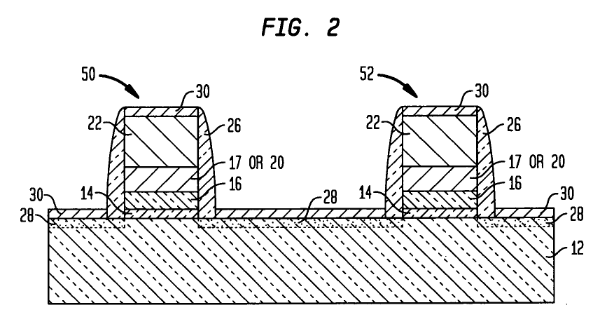

As stated above, the present invention provides a semiconductor structure and method wherein a fixed spatial distribution of electric charge density is introduced into the gate dielectric which is capable of controlling the threshold voltage and flatband voltage of a FET. The inventive structure which includes at least one gate stack on a semiconductor substrate, said at least one gate stack including, from bottom to top, a gate dielectric and a gate electrode, wherein said gate dielectric contains a fixed spatial distribution of electric charge density that stabilizes the gate stack's threshold voltage and flatband voltage to a targeted value, will now be described in greater detail by referring to FIGS. 1A-1F.

It is observed that these drawings illustrate the basic processing steps for forming the inventive semiconductor structure. Although FIGS. 1A-1F show a single FET, the present invention contemplates forming a plurality of FETs on a same semiconductor substrate. The plurality of FETs may have the same conductivity (i.e., all nFETs or all pFETs). Alternatively, the plurality of FETs may have different conductivities (i.e., some nFETs and some pFETs). When different plurality FETs are formed, the same basic processing steps as illustrated in FIGS. 1A-1F are employed except that block masks can be used to process one set of FETs, while protecting the other set of FETs.

Reference is first made to the initial structure 10 shown in FIG. 1A. Specifically, the initial structure 10 includes a semiconductor substrate 12 having disposed thereon, from bottom to top, an optional interfacial insulating 14 and a gate dielectric 16.

The semiconductor substrate 12 employed in the present invention comprises any semiconducting material including, but not limited to: Si, Ge, SiGe, SiC, SiGeC, Ga, GaAs, InAs, InP and all other III/V or II/VI compound semiconductors. Semiconductor substrate 12 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein.

When SOI substrates are employed, those substrates include top and bottom semiconductor, e.g., Si, layers that are separated at least in part by a buried insulating layer. The buried insulating layer includes, for example, a crystalline or non-crystalline oxide, nitride or any combination thereof. Preferably, the buried insulating layer is an oxide. Typically, the buried insulating layer is formed during initial stages of a layer transfer process or during an ion implantation and annealing process, such as, for example, SIMOX (separation by ion implantation of oxygen).

The substrate 12 may have a single crystal orientation or alternatively hybrid semiconductor substrates having surface regions of different crystal orientations can also be employed. The hybrid substrate allows for fabricating a FET upon a specific crystal orientation that enhances the performance of the specific FET formed. For example, the hybrid substrate allows for providing a structure in which a pFET can be formed on a (110) crystal orientation, while the nFET can be formed on a (100) crystal orientation. When a hybrid substrate is used, it may have SOI-like properties, bulk-like properties or a combination of SOI— and bulk-like properties.

The semiconductor substrate 12 may also include a first doped (n- or p-) region, and a second doped (n- or p-) region. For clarity, the doped regions are not specifically shown in the drawings of the present application. The first doped region and the second doped region may be the same, or they may have different conductivities and/or doping concentrations. These doped regions are known as “wells”.

At least one isolation region (not shown) is then typically formed into the semiconductor substrate 12. The isolation region may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process. Note that the at least one isolation region provides isolation between neighboring gate regions, typically required when the neighboring gates have opposite conductivities. The neighboring gate regions can have the same conductivity (i.e., both n- or p-type), or alternatively they can have different conductivities (i.e., one n-type and the other p-type).

After processing the semiconductor substrate 12, the interfacial layer 14 is optionally formed on the surface of the semiconductor substrate 12 by chemical oxidation. The optional interfacial layer 14 is formed utilizing a conventional wet chemical process technique that is well known to those skilled in the art. Alternatively, the interfacial layer 14 may be formed by thermal oxidation, oxynitridation or by vapor deposition. When the substrate 12 is a Si-containing semiconductor, the interfacial layer 14 is comprised of chemical oxide grown by wet processing, or thermally grown or deposited silicon oxide, silicon oxynitride or a nitrided silicon oxide. When the substrate 12 is other than a Si-containing semiconductor, the interfacial layer 14 may comprise a semiconducting oxide, a semiconducting oxynitride or a nitrided semiconducting oxide or any other interface dielectric such as, for example, one having a low interface trap density with the semiconducting material.

The thickness of the interfacial layer 14 is typically from about 0.4 to about 1.2 nm, with a thickness from about 0.6 to about 1 nm being more typical. The thickness, however, may be different after processing at higher temperatures, which are usually required during CMOS fabrication.

In accordance with an embodiment of the present invention, the interfacial layer 14 is a silicon oxide layer having a thickness from about 0.6 to about 1.0 nm that is formed by wet chemical oxidation. The process step for this wet chemical oxidation includes treating a cleaned semiconductor surface (such as a HF-last semiconductor surface) with a mixture of ammonium hydroxide, hydrogen peroxide and water (in a 1:1:5 ratio) at 65° C. Alternately, the interfacial layer 14 can also be formed by treating the HF-last semiconductor surface in ozonated aqueous solutions, with the ozone concentration usually varying from, but not limited to: 2 parts per million (ppm) to 40 ppm.

Next, a gate dielectric 16 is formed on a surface of the structure, either atop the optional interfacial layer 14, if present, or atop a surface of the substrate 12. The gate dielectric 16 can be formed by a thermal growth process such as, for example, oxidation, nitridation or oxynitridation. Alternatively, the gate dielectric 16 can be formed by a deposition process such as, for example, chemical vapor deposition (CVD), plasma-assisted CVD, metalorganic chemical vapor deposition (MOCVD), atomic layer deposition (ALD), evaporation, reactive sputtering, chemical solution deposition and other like deposition processes. The gate dielectric 16 may also be formed utilizing any combination of the above processes.

The gate dielectric 16 is comprised of an insulating material having a dielectric constant of about 4.0 or greater. All dielectric constants mentioned herein are relative to a vacuum unless otherwise noted. In one embodiment, the gate dielectric 16 comprises a high k material. The term “high k” denotes a dielectric having a dielectric constant of greater than 4.0, preferably greater than 7.0. Specifically, the gate dielectric 16 employed in the present invention includes, but is not limited to: an oxide, nitride, oxynitride and/or silicate including metal silicates and nitrided metal silicates. In one embodiment, it is preferred that the gate dielectric 16 is comprised of an oxide such as, for example, SiO₂, HfO₂, ZrO₂, Al₂O₃, TiO₂, La₂O₃, SrTiO₃, LaAlO₃, Y₂O₃, Ga₂O₃, GdGaO and mixtures thereof. Highly preferred examples of gate dielectrics 16 include HfO₂, hafnium silicate and hafnium silicon oxynitride.

The physical thickness of the gate dielectric 16 may vary, but typically, the gate dielectric 16 has a thickness from about 0.5 to about 10 nm, with a thickness from about 0.5 to about 3 nm being more typical.

At this point of the present invention, the fixed spatial distribution of electric charge density can be introduced into the gate dielectric 16. As such, the fixed spatial distribution of electric charge density is introduced in some embodiments after deposition of the gate dielectric 16, but prior to deposition of the gate electrode.

In one embodiment of the present invention, the fixed spatial distribution of electric charge density can be achieved by forming a different dielectric or dielectric stack atop the gate dielectric 16 which has a different charging characteristic. For example, when the gate dielectric 16 has a net positive charge, as is the case with high k dielectrics, such as ZrO₂, HfO₂, Y₂O₃, TiO₂, silicon nitride and silicon oxynitride, then at least one other dielectric material or dielectric stack having a net negative charging effect can be formed atop the gate dielectric 16. Such dielectrics having a negative charge include Al₂O₃, Al oxynitride or Al nitride. The opposite configuration is also contemplated wherein the gate dielectric 16 includes a net negative charge and the other dielectric material or material stack formed thereon has a net positive charge.

The other dielectric material (or dielectric material stack) is formed utilizing the same or different deposition technique has mentioned above in connection with gate dielectric 16. FIG. 1B illustrates a structure including the other dielectric 17 having the opposite charge disposed on the gate dielectric 16. The other dielectric 17 typically remains in the structure and is positioned between the gate dielectric 16 and the gate electrode 22 to be subsequently formed thereon. In some embodiments, the other dielectric 17 is removed, yet the charge is left behind within the gate dielectric 16. The deposition process of dielectric 17 creates charges in the gate dielectric 16 via chemical interaction and diffusion of atomic species and the density of charges created depends on the deposition conditions and anneals prior to removal of dielectric 17.

The thickness of the other dielectric 17 having the opposite charge than the gate dielectric 16 may vary depending on the number of materials used in forming the other dielectric 17 as well as the technique used in forming the same. The thickness of the other dielectric 17 of opposite charge than the gate dielectric 16 is typically from about 0.5 to about 4 nm.

Another means of providing the fixed spatial distribution of electric charge density to the gate dielectric 16 at this point of the present invention is to form an alkaline earth metal-containing material or a rare earth metal (or a rare earth-like) containing material on the gate dielectric. This layer 20 can be formed directly atop gate dielectric 16, or it can be formed atop the other dielectric material 17, if present. The former structure is shown in FIG. 1C, wherein reference numeral 20 denotes the alkaline earth metal-containing or rare-earth containing material. The alkaline earth metal-containing material comprises a compound having the formula MₓA_{y} wherein M is an alkaline earth metal (Be, Mg, Ca, Sr, and/or Ba), A is one of O, S or a halide, and x is 1 or 2 and y is 1, 2 or 3. It is noted that the present invention contemplates alkaline earth metal-containing compounds that include a mixture of alkaline earth metals and/or a mixture of anions, such as —OCl⁻². Examples of alkaline earth metal-containing compounds that can be used in the present invention include, but are not limited to: MgO, MgS, MgF₂, MgCl₂, MgBr₂, MgI₂, CaO, CaS, CaF₂, CaCl₂, CaBr₂, CaI₂, SrO, SrS, SrF₂, SrCl₂, SrBr₂, SrI₂, BaO, BaS, BaF₂, BaCl₂, BaBr₂, and BaI₂. In one preferred embodiment of the present invention, the alkaline earth metal-containing compound includes Mg. MgO is a highly preferred alkaline earth metal-containing material employed in the present invention.

The alkaline earth metal-containing material is formed utilizing a conventional deposition process including, for example, sputtering from a target, reactive sputtering of an alkaline earth metal under oxygen plasma conditions, electroplating, evaporation, molecular beam deposition, MOCVD, ALD, PVD and other like deposition processes. The alkaline earth metal-containing material typically has a deposited thickness from about 0.1 nm to about 3.0 nm, with a thickness from about 0.3 nm to about 1.6 nm being more typical.

When a rare earth metal-containing layer is used as on of the layers, the rare earth metal-containing layer comprises an oxide or nitride of at least one element from Group IIIB of the Periodic Table of Elements including, for example, La, Ce, Pr, Nd, Pm, Sm, Eu, Ga, Tb, Dy, Ho, Er, Tm, Yb, Lu or mixtures thereof. Preferably, the rare earth metal-containing layer comprises an oxide of La, Ce, Y, Sm, Er, and/or Th, with La₂O₃ or LaN being most preferred.

The rare earth metal-containing layer is formed utilizing a conventional deposition process including, for example, evaporation, molecular beam deposition, MOCVD, ALD, PVD and other like deposition processes. In one embodiment of the present invention, the rare earth metal-containing layer is formed by placing the structure into the load-lock of a molecular beam deposition chamber, followed by pumping this chamber down to the range of 10⁻⁵ to 10⁻⁸ Torr. After these steps, the structure is inserted, without breaking vacuum into the growth chamber where the rare earth metal-containing layer such as La oxide is deposited by directing atomic/molecular beams of the rare earth metal and oxygen or nitrogen onto the structure's surface. Specifically, because of the low pressure of the chamber, the released atomic/molecular species are beamlike and are not scattered prior to arriving at the structure. A substrate temperature of about 300° C. is used. In the case of La₂O₃ deposition, the La evaporation cell is held in the temperature range of 1400° to 1700° C., and a flow rate of 1 to 3 sccm of molecular oxygen is used. Alternatively, atomic or excited oxygen may be used as well, and this can be created by passing the oxygen through a radio frequency source excited in the range of 50 to 600 Watts. During the deposition, the pressure within the chamber can be in the range from 1×10⁻⁵ to 8×10⁻⁵ Torr, and the La oxide growth rate can be in the range from 0.1 to 2 nm per minute, with a range from 0.5 to 1.5 nm being more typical.

The rare earth metal-containing layer typically has a thickness from about 0.1 nm to about 3.0 nm, with a thickness from about 0.3 mn to about 1.6 nm being more typical.

The alkaline earth metal-containing material or a rare earth metal (or a rare earth-like) containing material 20 may remain in the structure or it can be removed after deposition, yet still effecting the fixed distribution of electric charge density within the gate dielectric 16. The fixed charge density is introduced via process damage, atomic diffusion and chemical reaction.

In still yet another embodiment of the present invention, the fixed distribution of electric charge density can be introduced into the gate dielectric 16 by a treatment step that can be performed at this point invention. The treatment step can be performed without any other material layer atop the gate dielectric or the treatment step can be performed with the other dielectric material 17 and/or the alkaline earth metal-containing material or a rare earth metal (or a rare earth-like) containing material 20 atop the gate dielectric 16.

The treatment step includes thermal, wet chemical, gas phase, plasma atomic, ion implantation, deposition or any combination thereof, performed in any sequence, after deposition of at least the gate dielectric 16.

When deposition is used as the treatment, the other dielectric material 17 or the alkaline earth metal-containing material or a rare earth metal (or a rare earth-like) containing material 20 is disposed on the gate dielectric 16. The deposition includes any of the techniques described above in forming either of layers 17 or 20.

When thermal treatment is used, the structure (with or without layers 17 and/or 20; layers 17 and/or 20 may have been deposited but removed prior to thermal treatment) is subjected to a heating step that is performed in an inert ambient such as He, Ar, Ne, N₂ or mixtures thereof at a temperature from about 200° to about 1000° C., with a temperature from about 400° to about 700° C. being more preferred. The heating step includes a rapid thermal anneal, a furnace anneal, a laser anneal, a spike anneal or a microwave anneal. The duration of the heating may vary depending on the exact technique used. Typically, the heating step is performed for a time period from about 0.005 seconds to about 1 minute when an anneal, other than a furnace anneal, is used. A furnace anneal may require a longer anneal time than the range provided herein. The thermal treatment is believed to introduce the fixed spatial distribution of electric charge density into the gate dielectric 16 by diffusion of the atomic species and reaction of these species with dielectric 16.

When wet chemical treatment is used, an oxidation agent or a reducing agent is used. Examples of oxidation agents include, but are not limited to: hydrogen peroxide. Examples of reducing agents include, but are not limited to: oxalic acid. The wet chemical treatment can be applied to the structure including the gate dielectric 16 (with or without layers 17 and/or 20) by utilizing techniques well known to those skilled in the art. For example, dip coating, spray coating, immersion, brushing and the like can be used for the application of the chemical agent to the structure. The wet chemical treatment is believed to introduce the fixed spatial distribution of electric charge density into the gate dielectric 16 by redox reactions with dielectric 16.

When a gas phase treatment is used, at least one foreign atom such as, for example oxygen, hydrogen, sulfur and the like are used. The at least one foreign atom is provided using a source which includes at least one of the foreign atoms and the source, if not already a gas, is converted into a gas utilizing techniques well known to those skilled in the art. The gas phase treatment is performed at a temperature from about 300° to about 750° C. for a time period from about 1 to about 120 minutes. More preferably, the gas phase treatment is performed at a temperature from about 400° to about 600° C. for a time period from about 2 to about 30 minutes. The gas phase treatment may be performed to a structure including the gate dielectric 16 which may or may not include layers 17 and/or 20. The gas phase treatment is believed to introduce the fixed spatial distribution of electric charge density into the gate dielectric 16 by atomic diffusion and chemical reaction with dielectric 16.

When a plasma treatment is used, the plasma treatment includes providing a plasma of hydrogen, oxygen, nitrogen, or fluorine, using an appropriate source such as, for example, molecular hydrogen or oxygen. The plasma is a neutral, highly ionized gas that consisting of neutral atoms or molecules, positive ions and free electrons. Ionization of the source is typically carried out in a reactor chamber in which the ionization process is achieved by subjecting the source to strong DC or AC electromagnetic fields. Alternatively, the ionization of the hydrogen source is performed by bombarding the gate atoms with an appropriate electron source. In accordance with the present invention, the plasma treatment is performed at a temperature from about 250° to about 600° C. The plasma treatment may be performed to a structure including the gate dielectric 16 which may or may not include layers 17 and/or 20. The plasma treatment is believed to introduce the fixed spatial distribution of electric charge density into the gate dielectric 16 by radical species.

When an atomic treatment is used, an atomic species such as, for example atomic oxygen, atomic hydrogen, nitrogen, fluorine and the like is first provided and then introduced to the structure including at least the gate dielectric 16; the structure may or may not include layers 17 and/or 20. The atomic treatment is performed utilizing the basic processing steps as described above for the plasma process. The atomic treatment is believed to introduce the fixed spatial distribution of electric charge density into the gate dielectric by atomic diffusion and/or chemical reaction.

When ion implantation is used, an ion such as, for example, oxygen, hydrogen, or flourine, is introduced into the structure including at least the gate dielectric 16 with layers 17 and/or 20 being optionally present. The ion implantation is performed at an energy from about 1 to about 12 keV, with an energy from about 5 to about 12 keV being more preferred. The ion implantation process is performed utilizing a dose of ions from about 1E15 to about 1E18 atoms/cm², with a dosage from about 5E15 to about 1E17 atoms/cm² being more highly preferred. The ion implantation may be performed in one step, or multiple ion implantation steps can be used.

Combinations of the above treatment processes such as deposition and thermal treatment are also contemplated. The deposited layer may be removed prior to the other treatment step or it may remain in the structure during the other treatment.

The above treatments steps may be repeated any number of times as desired or warranted to achieve the fixed spatial distribution of electric charge density to the gate dielectric 16.

Next a gate electrode 22 is formed on the upper exposed surface layer shown in FIG. 1A, 1B or 1C. The gate dielectric 16 may or may not have the fixed spatial distribution of electric charge density at this point of the inventive process. FIG. 1D shows a resultant structure that is formed by depositing the gate electrode 22 atop a structure including either layer 17 or 20. Although such a structure is shown, layers 17 or 20 are optional and may not be present and as such the gate electrode 22 can be formed on the gate dielectric 16. The gate electrode 22 is comprised of a conductive material, including, for example, polySi, SiGe, a metal, a metal alloy, a metal silicide, a metal nitride, a metal carbide or combinations including multilayers thereof. When multilayers are present, a diffusion barrier (not shown), such as TiN or TaN, can be positioned between each of the conductive layers. A capping layer (also not shown), such as an oxide, or nitride, can be located atop the gate electrode; the presence of the capping layer can be used to prevent subsequent formation of a silicide contact on said gate electrode. The silicide contact on said gate electrode is typically formed when the gate electrode includes a Si-containing material and no capping layer is present.

The gate electrode 22 is formed utilizing a conventional deposition process including for example, chemical vapor deposition, plasma enhanced chemical vapor deposition, atomic layer deposition, sputtering, plating, evaporation and any other like deposition processes. In embodiments in which poly Si or SiGe are used as the gate electrode, an in-situ deposition process can be used or alternatively deposition followed by ion implantation can be used.

The thickness of the gate electrode 22 is not critically to the present invention. Typically, however, thickness of the gate electrode is from about 1 to about 50 nm.

At this point of the present invention, and if not previously done, the fixed spatial charge density can be introduced into the gate dielectric 16. When the fixed spatial charge density is introduced into the gate dielectric 16 with the gate electrode 22 disposed thereon, one of the above treatment steps can be performed. Of the treatments, those including chemical treatment are preferably used when the gate electrode 22 is formed on the structure. It is noted that the fixed spatial distribution of electric charge density can occur anytime after the gate electrode 22 has been formed provided that the fixed charge is introduced before voltages or currents are applied to the silicide contacts.

After the gate electrode 22 has been deposited, lithography and etching are used in patterning at least the gate electrode 22 and typically the gate dielectric 16 into at least one gate stack 23 as shown in FIG. 1E. Although the structure shown in FIG. 1E includes the optional layer 17 or 20, that layer may not be present at this point of the present invention.

The lithography step includes applying a conventional photoresist (not shown) on a surface of the gate electrode 22, exposing the photoresist to a desired pattern of radiation and developing the exposed resist utilizing a conventional resist developer. The etching step includes dry etching (such as, for example, reactive ion etching, plasma etching, ion beam etching or laser ablation), wet chemical etching or any combination of said etching processes.

At least one spacer 26 is then typically formed on the exposed sidewalls of the at least one gate stack 23 utilizing deposition and etching. The at least one spacer 26, which is optionally present, is typically comprised of an oxide, nitride or oxynitride including combinations and multilayers thereof. Although optional, typically one spacer 26 is present in the inventive structure. In some embodiments, a passivation layer (not shown) can be formed prior to the formation of the at least one spacer utilizing conventional techniques well known to those skilled in the art. When present, the passivation layer is typically comprised of an oxide, nitride or oxynitride.

At this point of the present invention, S/D regions 28 are formed into the substrate 12 by utilizing conventional ion implantation and activation annealing. The S/D regions 28 typically include extension regions and deep S/D diffusion regions. The source/drain regions 28 together with the gate electrode 22 define the length of the channel of the FET. It is noted that S/D extensions and S/D diffusion regions are comprised of an upper portion of the semiconductor substrate 12 that has been doped with either n- or p-type dopants by ion implantation. The S/D extensions are typically shallower in depth than the S/D diffusion regions.

Next, silicide contacts 30 are typically formed at least on the S/D regions 28 utilizing a conventional silicidation process. Silicide contacts can also be formed atop the gate electrode 22, when the gate electrode 22 is comprised of polySi or SiGe.

The silicidation process includes forming a metal or metal alloy atop the structure that is capable of reacting with silicon to form a silicide on the structure, and then performing at least one silicide anneal step. In some embodiments, first and second annealing steps are used. An optional Si-containing layer can be formed prior to the formation of the metal layer and an optional diffusion barrier can be formed atop the metal layer, which is removed from the structure after the first anneal. The metal used in forming the silicide contacts includes one of Co, Ti, Ni, Pt, W, or alloys thereof which may include an alloying additive.

The resultant structure including the at least one spacer 26, the S/D regions 28 and the silicide contacts 30 is shown in FIG. 1F. At this point of the present invention, conventional interconnect technology can be used to provide one or more interconnect levels to the structure shown in FIG. 1F. The one or more interconnect levels basically include a dielectric material that has conductive features (lines, vias or vias and lines) formed therein.

If not previous done, the fixed spatial distributed of charge density can be introduced into the gate dielectric 16 at this point of the present invention by applying a voltage or current to the silicide contacts 30. The voltage or current is applied utilizing techniques well known to those skilled in the art.

It has been determined that by having a fixed spatial distribution of electric charge density in the gate dielectric 16 a stabilized gate stack structure, in terms of the threshold voltage and flatband voltage, can be achieved. In particular, when applying a bias to the inventive gate stack structure including the fixed spatial distribution of electric charge density the presence of the fixed charge stabilizes the structure's threshold voltage and flatband voltage to a targeted value that is within ranges normal associated with nFET and pFET devices.

FIG. 2 shows an inventive structure including at least one nFET 50 and at least one pFET 52 located on a surface of a semiconductor substrate 12. Each FET includes a gate stack including, from bottom to top, a gate dielectric 16 and a gate electrode 22, wherein said gate dielectric of said at least one nFET contains a first fixed spatial distribution of electric charge density and said gate dielectric of said at least one pFET includes a second fixed spatial distribution of electric charge density that is different from said first, wherein each of the first and second fixed spatial charge densities stabilizes its FET's threshold voltage and flatband voltage to a targeted value. The gate dielectric 16 and the gate electrode 22 of the each of the FETs may be the same or different material.

While the present invention has been particularly shown and described with respect to preferred embodiments thereof, it will be understood by those skilled in the art that the foregoing and other changes in forms and details may be made without departing from the scope and the spirit of the present invention. It is therefore intended that the present invention not be limited to the exact forms and details described and illustrated, but fall within the scope of the appended claims.

What is claimed is:

1. A semiconductor structure comprising:
at least one gate stack disposed on a semiconductor substrate, said gate stack including, from bottom to top, a gate dielectric and a gate electrode, wherein said gate dielectric contains a fixed spatial distribution of electric charge density that stabilizes the gate stack's threshold voltage and flatband voltage to a targeted value.

2. The semiconductor structure of claim 1 wherein said semiconductor substrate comprises Si, Ge, SiGe, SiC, SiGeC, Ga, GaAs, InAs, InP other III/V or II/VI compound semiconductors, organic semiconductors or layered semiconductors.

3. The semiconductor structure of claim 1 wherein said semiconductor substrate is a hybrid substrate including surface regions of different crystallographic orientation.

4. The semiconductor structure of claim 1 further comprising an interfacial insulating layer located between said semiconductor substrate and said gate dielectric.

5. The semiconductor structure of claim 1 wherein said at least one gate stack is an nFET.

6. The semiconductor structure of claim 1 wherein said at least one gate stack is a pFET

7. The semiconductor structure of claim 1 wherein said fixed spatial distribution of electric charge density is from about 1×10¹² to about 1×10¹³ cm⁻².

8. A semiconductor structure comprising:
at least one nFET and at least one pFET located on a semiconductor substrate, each FET including a gate stack including, from bottom to top, a gate dielectric and a gate electrode, wherein said gate dielectric of said at least one nFET contains a first fixed spatial distribution of electric charge density and said gate dielectric of said at least one pFET includes a second fixed spatial distribution of electric charge density that is different from said first, wherein each of the first and second fixed spatial electric charge densities stabilizes its FET's threshold voltage and flatband voltage to a targeted value.

9. The semiconductor structure of claim 8 wherein said semiconductor substrate comprises Si, Ge, SiGe, SiC, SiGeC, Ga, GaAs, InAs, InP other III/V or II/VI compound semiconductors, organic semiconductors or layered semiconductors.

10. The semiconductor structure of claim 8 wherein said semiconductor substrate is a hybrid substrate including surface regions of different crystallographic orientation, wherein said at least one nFET is located on a (100) surface and said at least one pFET is located on a (110) surface.

11. The semiconductor structure of claim 8 wherein said first fixed spatial distribution of electric charge density is from about 1×10¹² to about 1×10¹³ cm⁻² and said second fixed spatial distribution of electric charge density is from about 1×10¹³ to about 5×10¹³ cm⁻².

12. A method of forming a semiconductor structure comprising:
providing a gate stack on a semiconductor substrate, said gate stack including, from bottom to top, a gate dielectric and gate electrode; and
applying a bias to said gate stack, wherein said gate dielectric contains a fixed spatial distribution of electric charge density that stabilizes the gate stack's threshold voltage and flatband voltage to a targeted value.

13. The method of claim 12 wherein said fixed spatial distribution of electric charge density is introduced during or after deposition of the gate dielectric, but prior to the deposition of the gate electrode.

14. The method of claim 12 wherein said fixed spatial distribution of electric charge density is introduced during or after deposition of the gate electrode, but prior to applying voltages or currents to contact regions.

15. The method of claim 12 wherein said fixed spatial distribution of electric charge density is introduced by applying a voltage or a current to contact regions.

16. The method of claim 12 wherein said fixed spatial distribution of electric charge density is introduced by a treatment process selected from the group consisting of thermal, wet, gas phase, plasma, atomic, ion implantation, deposition and combinations thereof.

17. The method of claim 12 wherein said fixed spatial distribution of electric charge density is introduced by deposition of one or more layers onto the gate dielectric, treating the one or more layers and removing the one or more layers.

18. The method of claim 12 wherein said fixed spatial distribution of electric charge density is introduced by deposition of one or more layers onto the gate electrode, treating the one or more layers and removing the one or more layers.

19. The method of claim 12 wherein said fixed spatial distribution of electric charge density is introduced by a treatment process selected from the group consisting of thermal, wet, gas phase, plasma, atomic, ion implantation, deposition and combinations thereof, that are performed after depositing said gate electrode.

20. The method of claim 12 wherein a plurality of gate stacks are formed in which a first set of gate stacks have a first conductivity and a second set of gate stacks has a second conductivity that differs from the first conductivity, wherein each gate stack within the first set has a first fixed spatial distribution of electric charge density and each gate stack within said second set has a second fixed spatial distribution of electric charge density which differs from the first fixed spatial distribution of electric charge density.
